(19) United States
(12) Patent Application Publication
(10) Pub. No.: US 2025/0260376 A1
(43) Pub. Date: Aug. 14, 2025

(54) Hybrid Couplers with Asymmetric Port Impedances for Balanced Amplifiers and Load-Modulated Balanced Amplifiers

(71) Applicant: QUALCOMM Incorporated, San Diego, CA (US)

(72) Inventors: Lei MA, Palo Alto, CA (US); Kun WANG, Sunnyvale, CA (US)

(21) Appl. No.: 18/440,782

(22) Filed: Feb. 13, 2024

(51) Int. Cl. H03F 3/60; H03F 1/56

(52) U.S. Cl. CPC H03F 3/602; H03F 1/56; H03F 2200/198; H03F 2200/204; H03F 2200/451

(57) ABSTRACT

A dual-amplifier system is provided that may comprise a balanced amplifier or a load-modulated balanced amplifier. The dual-amplifier system includes a first amplifier for amplifying a first RF signal into an amplified first RF signal and includes a second amplifier for amplifying a second RF signal into an amplified second RF signal. An impedance-transforming quadrature hybrid combiner is configured to receive the amplified first RF signal and the amplified second RF signal to combine them into an RF output signal.

### TECHNICAL FIELD

This application relates to hybrid couplers, and more particularly to hybrid couplers with asymmetric port impedances for balanced amplifiers and load-modulated balanced amplifiers.

### BACKGROUND

A balanced amplifier uses two identical amplifiers fed by an input hybrid coupler that functions as a splitter and thus receives an input signal at an input port and splits the input signal equally such that an amplifier input signal to each amplifier has one-half the power (−3 dB) of the input signal power. The input hybrid coupler may also be denoted as a quadrature hybrid splitter since it is designed to produce a 90-degree phase shift between the amplifier input signals. One amplifier couples to a coupled port of the quadrature hybrid splitter whereas another couples to a through port of the quadrature hybrid splitter. The quadrature relationship between the split signals at the coupled and through ports results in the reflections to an isolated port of the input hybrid coupler from the input terminals of the two amplifiers being antipolar to each other such that (ideally) no reflected energy is diverted to the isolated port.

A quadrature hybrid combiner combines the amplified output signals from the pair of amplifiers and is designed to be symmetric with the quadrature hybrid splitter. In a balanced amplifier configuration, an isolated port of the quadrature hybrid combiner couples to ground through a matching impedance. However, in a load-modulated balanced amplifier, an auxiliary amplifier drives the isolated port of the quadrature hybrid combiner.

### SUMMARY

In accordance with an aspect of the disclosure, a dual-amplifier system is provided that comprises: a first amplifier having an output impedance at a first output terminal; a second amplifier having the output impedance at a second output terminal; a quadrature hybrid combiner having a through port impedance and a coupled port impedance each equaling an intermediate impedance that is greater than the output impedance and having an output port impedance equaling a load impedance that is greater than the intermediate impedance; a first impedance matching network coupled between the first output terminal and a coupled port of the quadrature hybrid combiner, wherein the first impedance matching network is configured to match the output impedance to the intermediate impedance; and a second impedance matching network coupled between the second output terminal and a through port of the quadrature hybrid combiner, wherein the second impedance matching network is configured to match the output impedance to the intermediate impedance

In accordance with another aspect of the disclosure, a method of operation for a dual-amplifier system is provided that comprises: coupling an amplified first RF signal from a first amplifier to a coupled port of a quadrature hybrid combiner having a coupled port input impedance equaling an output impedance of the first amplifier; coupling an amplified second RF signal from a second amplifier to a through port of the quadrature hybrid combiner having a through port input impedance equaling an output impedance of the second amplifier; combining the amplified first RF signal and the amplified second RF signal to produce an RF output signal at an output port of the quadrature hybrid combiner having an output port impedance that is less than an input impedance of a load; and coupling the RF output signal through an impedance matching network to the load, wherein the impedance matching network matches the output port impedance to the input impedance of the load.

In accordance with yet another aspect of the disclosure, a dual-amplifier system is provided that includes: a first amplifier configured to amplify a first RF signal into an amplified first RF signal at a first output terminal having an output impedance; a second amplifier configured to amplify a second RF signal into an amplified second RF signal at a second output terminal having the output impedance; and a quadrature hybrid combiner including a coupled port coupled to the first output terminal and including a through port coupled to the second output terminal, wherein an input impedance of each of the coupled port and the through port equals the output impedance.

These and other advantageous features may be better appreciated through the following detailed description.

### BRIEF DESCRIPTION OF THE DRAWINGS

FIG. 1 illustrates a traditional balanced amplifier.

FIG. 2 illustrates a balanced amplifier in which a quadrature hybrid combiner is configured to impedance transform from an intermediate impedance at the coupled and through ports to a load impedance at the output port in accordance with an aspect of the disclosure.

FIG. 3 illustrates a load-modulated balanced amplifier in which a quadrature hybrid combiner is configured to impedance transform from an intermediate impedance at the coupled and through ports to a load impedance at the output port in accordance with an aspect of the disclosure.

FIG. 4 illustrates a load-modulated balanced amplifier in which an output terminal of a first amplifier couples directly to a coupled port of a quadrature hybrid combiner without an intervening impedance transformation and in which an output terminal of a second amplifier couples directly to a through port of the quadrature hybrid combiner without an intervening impedance transformation in accordance with an aspect of the disclosure.

FIG. 5 is a circuit representation of a quadrature hybrid combiner configured for a 1:2 impedance transformation in accordance with an aspect of the disclosure.

FIG. 6 illustrates an inductor of the quadrature hybrid combiner of FIG. 5 formed as a loop from a patterned metal layer in accordance with an aspect of the disclosure.

FIG. 7 is a flowchart for a method of operation for a dual-amplifier system including an impedance-transforming quadrature hybrid combiner in accordance with an aspect of the disclosure.

FIG. 8 is a diagram of a wireless communication device having a transceiver and a dual-amplifier system in accordance with an aspect of the disclosure.

Implementations of the present disclosure and their advantages are best understood by referring to the detailed description that follows. It should be appreciated that like reference numerals are used to identify like elements illustrated in one or more of the figures.

### DETAILED DESCRIPTION

Radio Frequency (RF) systems are generally impedance matched as otherwise undesirable reflections occur from impedance mismatches. For a variety of historical and also practical reasons, input and output impedances are commonly matched to a characteristic impedance of 50 Ohms. However, other load impedances may be used so long as an RF system is impedance matched to the desired load impedance. It is thus traditional that the four ports of a quadrature hybrid combiner for a balanced amplifier (or a load-modulated balanced amplifier) are designed to present a 50 Ohm impedance. The following discussion will assume that the desired load impedance is 50 Ohms since this is traditional but it will be appreciated that other load impedances may be used for alternative implementations.

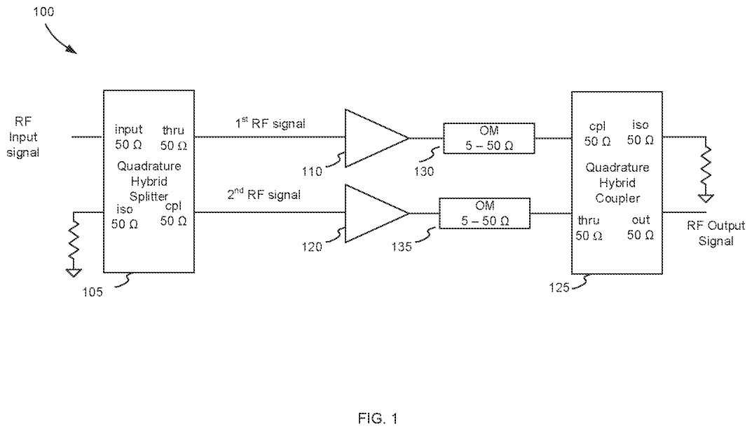

The term “dual-amplifier system” is used herein to refer generically to either a balanced amplifier or a load-modulated balanced amplifier. Given this nomenclature definition, a dual-amplifier system is provided that includes a quadrature hybrid combiner whose four ports are not impedance matched to the load impedance (e.g., 50 Ohms (Ω)). To better illustrate the advantages of such a dual-amplifier system, an example traditional dual-amplifier system will first be discussed. An example traditional balanced amplifier 100 with a quadrature hybrid splitter and a quadrature hybrid combiner matched for a 50 Ω load impedance is shown in FIG. 1. A quadrature hybrid splitter 105 receives a radio frequency (RF) input signal at an input port that has a characteristic impedance of 50 Ω. The quadrature hybrid splitters splits the RF input signal by 3 dB into a first RF signal at a through (thru) port and into a second RF signal at a coupled (cpl) port. A phase of the second RF signal is in quadrature with a phase of the first RF signal. Like the input port, the through port, the coupled port, and an isolated port of the quadrature hybrid splitter all have a characteristic impedance of 50 Ω. A first amplifier 110 amplifies the first RF signal. Similarly, a second amplifier 120 amplifies the second RF signal. But an output impedance of the first and second amplifiers 110 and 120 is relatively low. For example, each of the first and second amplifiers 110 and 120 may include a bipolar junction transistor (not illustrated) having a collector terminal forming the output terminal for each amplifier. An output impedance of the amplifiers 110 and 120 may thus be relatively low such as 5 ohms. A matching network 130 thus matches the 5 Ω output impedance of the first amplifier 110 to the desired load impedance of 50 ohms. Similarly, a matching network 135 matches the 5 Ω output impedance of the second amplifier 120 to the desired load impedance of 50 ohms.

The first amplifier 110 amplifies the first RF signal to produce an amplified first RF signal that couples through the matching network 130 to a coupled port of a quadrature hybrid combiner 125. Similarly, the second amplifier 120 amplifies the second RF signal to produce an amplified second RF signal that couples through the matching network 135 to a through port of the quadrature hybrid combiner 125. The quadrature hybrid combiner 125 combines the amplified first and second RF signals with a quadrature phase relationship to produce an RF output signal at an output port (out) of the quadrature hybrid combiner 125. Note that the quadrature hybrid combiner 125 is symmetric with the quadrature hybrid splitter 105 except that what was the input port of the quadrature hybrid splitter 105 becomes an output port of the quadrature hybrid combiner 125. The through, coupled, and output port of the quadrature hybrid combiner 125 along with its isolated port thus all have an impedance of 50 ohms.

The isolated port of the quadrature hybrid combiner 125 couples to ground through a matched 50 Ω load. Should the isolated port instead be driven by an auxiliary power amplifier (not illustrated), the traditional balanced amplifier 100 would be transformed into a traditional load-modulated balanced amplifier. Regardless of whether a balanced amplifier or a load-modulated balanced amplifier architecture is used, note that the matching network loss from the matching networks 130 and 135 as well as the loss within the quadrature hybrid combiner 125 negatively affect the power-added efficiency (PAE).

To provide increased PAE and also reduce manufacturing costs and provide increased bandwidth and other benefits, a power amplifier topology for either a balanced amplifier or a load-modulated balanced amplifier is disclosed herein in which the output impedances of the first and second amplifiers is not matched through corresponding impedance matching networks to the load impedance (e.g., to 50 ohms) but instead to some reduced intermediate impedance such as 25 or even 10 Ω. In yet another implementation, no impedance matching networks intervene between the first and second amplifiers and the quadrature hybrid combiner. Regardless of whether impedance matching networks are included, the quadrature hybrid combiner then functions to transform the impedance from its through and coupled ports to an output port impedance at its output port. This transformation is a 1:N transformation in some implementations, where N is a positive real number greater than one. Due to the symmetry within the quadrature hybrid combiner, the isolated port impedance would then have a 1:N relationship to the through and coupled port impedances. For example, suppose that N is two and that the load impedance is 50 ohms. In one implementation, the through and coupled port impedance may then be equal to 25 ohms such that the output port impedance would also be 50 ohms and the isolated port impedance would be 12.5 ohms due to the 1:2 impedance transformation. In another implementation, the through and coupled port impedances may be 5 ohms such that the output port impedance would be 10 ohms and the isolated port impedance would be 2.5 Ω. It will be appreciated that these impedance values are merely non-limiting examples of the impedance transformations disclosed herein. In a balanced amplifier implementation, the isolated port couples to ground through a load that has a matching impedance to the isolated port impedance.

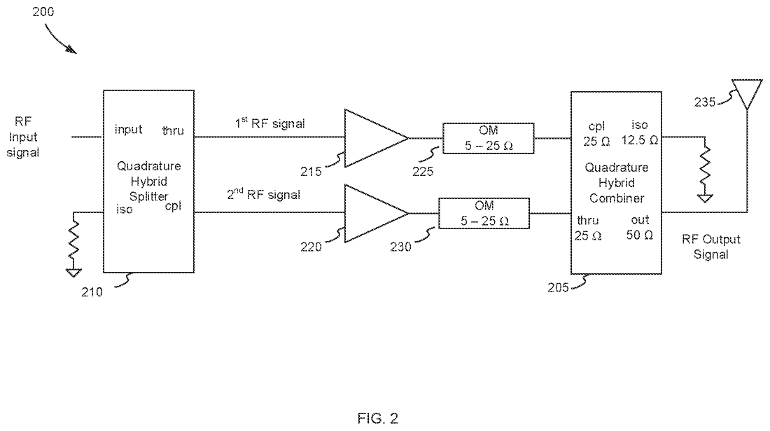

An example balanced amplifier 200 with an impedance-transforming quadrature hybrid combiner 205 is shown in FIG. 2. A quadrature hybrid splitter 210 functions to split an RF input signal into a first RF signal and a second RF signal analogously as discussed for the quadrature hybrid splitter 105. A first amplifier 215 amplifies the first RF signal to form an amplified first RF signal that is received by a first impedance matching network 225. An output impedance of the first amplifier 215 is 5 ohms as discussed analogously for the first amplifier 110. For example, an output terminal of the first amplifier 215 may be a collector terminal of a bipolar junction transistor (not illustrated). But note that the first impedance matching network 225 does not step up from the output impedance of the first amplifier 225 to the load impedance (e.g. to 50 ohms) but instead to just 25 ohms. More generally, the first impedance matching network 225 may step up the relatively low output impedance of the first amplifier 215 to some intermediate impedance that is less than the load impedance and greater than the output impedance of the first amplifier 215. After being impedance matched through the first impedance matching network 225, the amplified first RF signal is received at the coupled port of the quadrature hybrid combiner 205. An impedance of the coupled port in the quadrature hybrid combiner is thus matched to the output impedance of the impedance matching network 225. In the balanced amplifier 200, this output impedance is 25 ohms but it will be appreciated that 25 ohms is just an example of an intermediate impedance as discussed for the impedance matching network 225.

The second amplifier 220 amplifies the second RF signal to form an amplified second RF signal that is impedance matched through a second impedance matching network 230 to be received at the through port of the quadrature hybrid combiner 205. As discussed for the first impedance matching network 225, the second impedance matching network 230 may match a 5 Ω output impedance of the second amplifier 220 to a 25 Ω impedance of a through port of the quadrature hybrid combiner 205. More generally, the through port impedance may equal the intermediate impedance as discussed for the coupled port impedance. In such an implementation, the second impedance matching network 230 would match the relatively-low output impedance of the second amplifier 220 to the intermediate impedance.

The quadrature hybrid combiner 205 combines the amplified first and second RF signals from the first and second impedance matching networks 225 and 230 with a quadrature phase relationship to produce an RF output signal at an output port (out) of the quadrature hybrid combiner 205. As will be explained further herein, the quadrature hybrid combiner 205 is configured to perform an impedance transformation with respect to this combining such that an output impedance of the output port of the quadrature hybrid combiner 205 is the load impedance (e.g., 50 ohms). In this fashion, the RF output signal can drive a load having the load impedance such as an antenna 235 without any intervening impedance matching network. The resulting impedance transformation through the quadrature hybrid combiner 205 and the first and second impedance matching networks 225 and 230 results in improved PAE for the balanced amplifier 200 as compared to the use of a load-impedance-matched hybrid coupler such as the 50 Ω matching throughout the balanced amplifier 100. Quadrature hybrid splitter 210 may have analogous port impedances as discussed for the quadrature hybrid combiner 205. Alternatively, the port impedances of the quadrature hybrid splitter 210 may all be matched to a load impedance as discussed for the quadrature hybrid splitter 105.

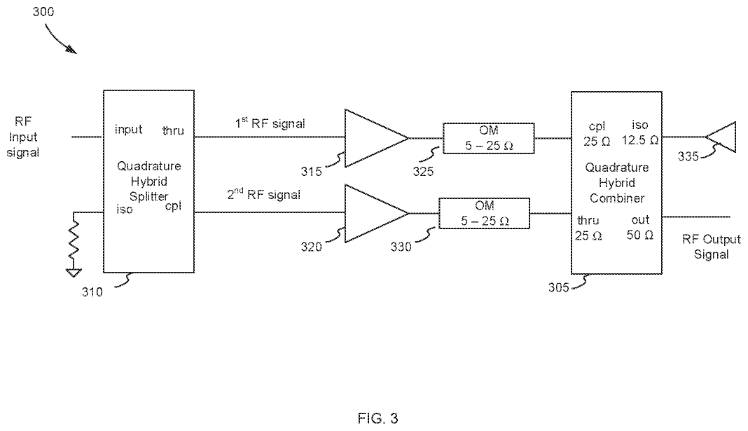

Balanced amplifier 200 may be transformed into a load-modulated balanced amplifier 300 as shown in FIG. 3. A quadrature hybrid splitter 310, a first amplifier 315, a second amplifier 320, a first impedance matching network 325, a second impedance matching network 330, and a quadrature hybrid combiner 305 are configured analogously to the respective elements in the balanced amplifier 200. However, an auxiliary amplifier 335 drives the isolated port of the quadrature hybrid combiner 305 rather than a matching load. An output impedance of the auxiliary amplifier 335 matches the isolated port impedance. The load-modulated balanced amplifier 300 shares the same advantages as discussed for balanced amplifier 200.

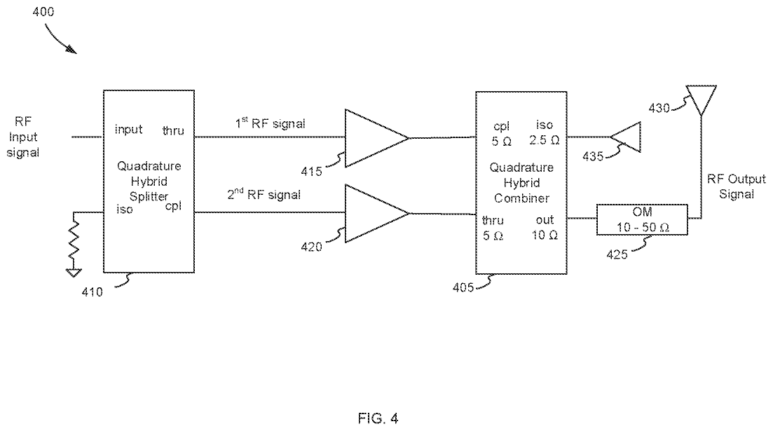

Since impedance matching networks introduce loss, it may be beneficial to directly couple the first and second amplifiers in a balanced amplifier and/or a load-modulated balanced amplifier directly to the quadrature hybrid combiner without any intervening impedance matching networks. But recall that the output impedance of the first and second amplifiers is often relatively low such as 5 ohms. A dual-amplifier system architecture is thus disclosed herein in which the through and coupled port impedances of the quadrature hybrid combiner match this relatively low impedance. An example load-modulated balanced amplifier 400 is shown in FIG. 4. A quadrature hybrid splitter 410 splits an input RF signal into a first RF signal and a second RF signal analogously as discussed for the quadrature hybrid splitters 105, 210, and 310. A first amplifier 415 amplifies the first RF signal to form an amplified first RF signal that is received at the coupled port of a quadrature hybrid combiner 405 without any intervening impedance matching network. An output terminal of the first amplifier 415 (e.g., a collector terminal) thus directly couples to the coupled port. A coupled port impedance of the quadrature hybrid combiner 405 equals the relatively low output impedance of the first amplifier 415 such as 5 ohms. A second amplifier 420 amplifies the second RF signal to form an amplified second RF signal that is received at a through port of the quadrature hybrid combiner 405 without any intervening impedance matching network. An output terminal of the second amplifier 420 (e.g., a collector terminal) thus directly couples to the through port. A through port impedance of the quadrature hybrid combiner 405 equals 5 ohms. It will be appreciated, however, that the 5 Ω output impedance of the first and second amplifiers 415 and 420 is exemplary and may be either higher or lower depending upon the amplifier implementation.

The quadrature hybrid combiner 405 is configured to perform a 1:2 impedance transformation in combining the amplified first and second RF signals to form an RF output signal at an output port. More generally, the quadrature hybrid combiner 405 may perform a 1:N impedance transformation, where N is a positive real number greater than one. Since the coupled and through port impedances are 5 ohms, the output port impedance is 10 ohms for a 1:2 impedance transformation. Given that a load such as at least one antenna 430 may be matched to 50 ohms, the output port couples to the antenna 430 through an impedance matching network 425 that matches the 10 Ω output impedance of the output port to the load impedance (e.g., 50 ohms) of the antenna 430. More generally, the output port impedance may be some intermediate impedance that is greater than the through/coupled port impedances but less than the load impedance. This intermediate impedance would equal N times the through/coupled port impedance given the 1:N impedance transformation. An auxiliary amplifier 435 drives the isolated port of the quadrature hybrid combiner 405. Due to the 1:N impedance transformation, an input impedance of the isolated port is 1/Nth the input impedance of the through and coupled ports. Should N equal two and the through and coupled port input impedances equal 5 ohms, the input impedance of the isolated port would equal 2.5 ohms. An output impedance of the auxiliary amplifier 435 is matched to the isolated port input impedance. In a balanced amplifier implementation, the isolated port would instead couple to ground through a load having an impedance equaling the isolate port input impedance.

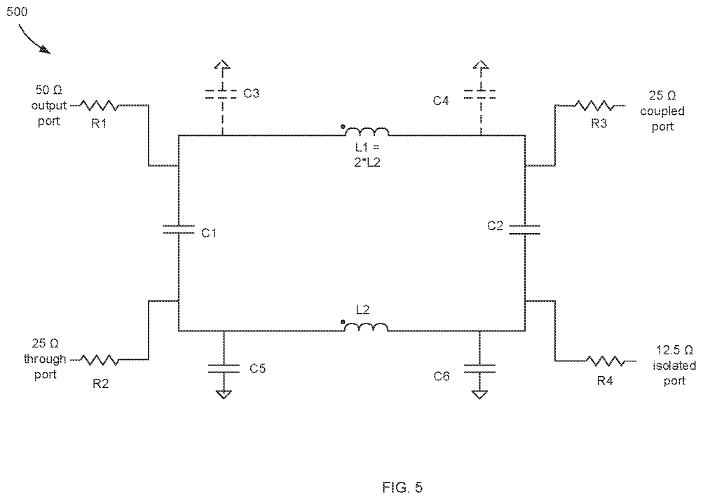

A circuit representation of an example impedance-transforming quadrature hybrid combiner 500 that transforms from coupled port/through port input impedance of 25 ohms to an output port impedance of 50 ohms is shown in FIG. 5. A resistor R1 represents the load impedance (e.g., 50 ohms) of the output port. Similarly, resistors R2 and R3 represents the intermediate impedance (e.g, 25 ohms) of the through and coupled ports, respectively. A capacitor C1 couples between the output port and the through port. Similarly, a capacitor C2 couples between the coupled port and the isolated port. An inductor L2 couples between the through port and the isolated port. Similarly, an inductor L1 couples between the output port and the coupled port. In a traditional (50 ohm port impedance) quadrature hybrid combiner an inductance of inductor L1 would equal an inductance of inductor L2. But to provide a 1:2 impedance transformation from the through and coupled ports to the output port, the inductance of inductor L1 equals twice the inductance of inductor L2. A coupling capacitor C5 couples between the through port and ground. Similarly, a coupling capacitor C6 couples between the isolated port and ground. But note that a coupling capacitor C3 that couples between the output port and ground as well as a coupling capacitor C4 that couples between the coupled port and ground are optional as the 1:2 impedance transformation results in the desired capacitance for these coupling capacitors being very small. Capacitors C3 and C4 may thus be omitted whereas they may be necessary in a traditional (50 Ω port impedance) design. In this fashion, the impedance transformation not only increases bandwidth and amplifier efficiency but also reduces the manufacturing cost of the quadrature hybrid combiner. Note that an analogous reduction of the component count is also enjoyed by the impedance transformation networks 225, 230, 325, and 330 as compared to the impedance transformation networks 130 and 135 that are transforming from the relatively low output impedance of the first and second amplifiers to a load impedance (e.g., 50 ohms).

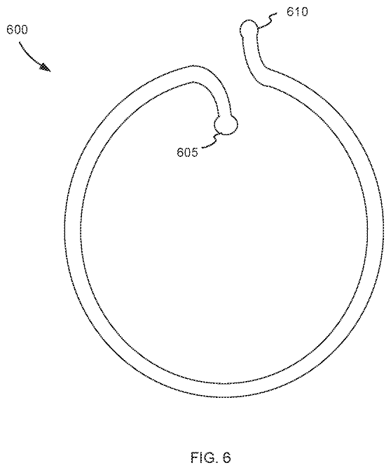

Due to the 1:2 impedance transformation in the quadrature hybrid combiner 500, an input impedance of the isolated port is 12.5 ohms as represented by a resistor R4. It will be appreciated that the circuit diagram representation of the quadrature hybrid combiner 500 shown in FIG. 5 is conceptual in that the various components may be implemented using lumped elements or instead through a distributed transmission line construction such as through stripline or microstrip. In a lumped-element construction, the various lumped elements may be integrated with respect to a laminate substrate. For example, the inductors may be formed in corresponding patterned metal layers adjacent the laminate substrate. An example inductor 600 patterned from a metal layer is shown in FIG. 6. A via 605 couples to a first end of the inductor 600. Similarly, a via 610 couples to a second end of the inductor 600. These vias provide the coupling between inductor 600 and the remaining components of the corresponding impedance-transforming quadrature hybrid coupler. Inductor 600 is formed in a first metal layer adjacent a laminate substrate. Note that inductors L1 and L2 are magnetically coupled. Another inductor (not illustrated) may thus be formed in a second metal layer adjacent the first metal layer to form a loop that aligns with the loop formed by inductor 600 so that the two inductors may magnetically couple to each other. Depending upon the loop construction and the number of metal layers used for a given inductor, the desired impedance transformation may be achieved.

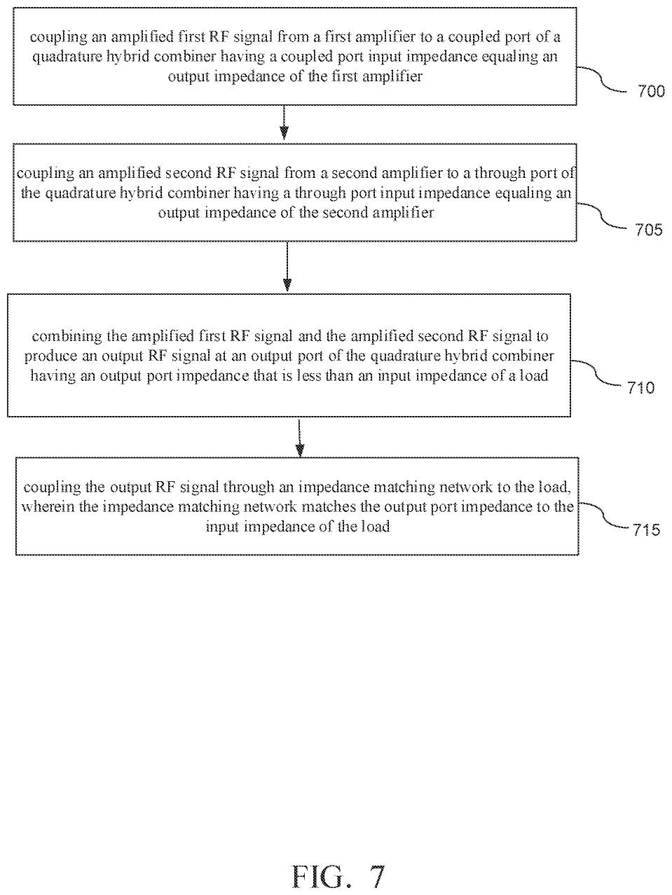

An example dual-amplifier method of operation will now be discussed with respect to the flowchart of FIG. 7. The method includes an act 700 of coupling an amplified first RF signal from a first amplifier to a coupled port of a quadrature hybrid combiner having a coupled port input impedance equaling an output impedance of the first amplifier. The direct coupling of the amplified first RF signal from an output terminal of the first amplifier 415 to the coupled port of the quadrature hybrid combiner 405 of FIG. 4 is an example of act 700. The method also includes an act 705 of coupling an amplified second RF signal from a second amplifier to a through port of the quadrature hybrid combiner having a through port input impedance equaling an output impedance of the second amplifier. The direct coupling of the amplified second RF signal from an output terminal of the second amplifier 420 to the through port of the quadrature hybrid combiner 405 is an example of act 705. In addition, the method includes an act 710 of combining the amplified first RF signal and the amplified second RF signal to produce an output RF signal at an output port of the quadrature hybrid combiner having an output port impedance that is less than an input impedance of a load. The formation of the output RF signal at the output port of the quadrature hybrid combiner 405 is an example of act 710. Finally, the method includes an act 715 of coupling the output RF signal through an impedance matching network to the load, wherein the impedance matching network matches the output port impedance to the input impedance of the load. The impedance transformation through the impedance matching network 425 of the output RF signal to drive the antenna 430 is an example of act 715.

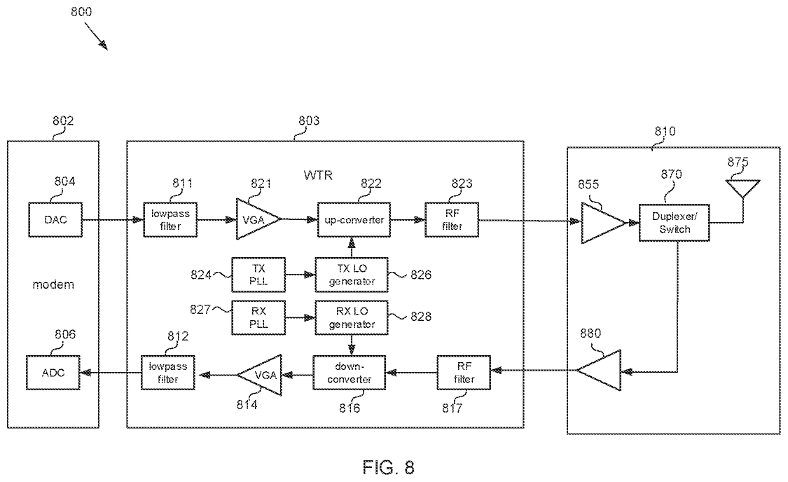

A dual-amplifier system as disclosed herein may be incorporated into any suitable transceiver within a wireless communication device. An example wireless communication device 800 is shown in FIG. 8. A modem 802 (which may also be denoted as a baseband processor) includes at least one digital-to-analog converter (DAC) 104 for generating an analog transmit signal. A wireless transceiver integrated circuit (WTR) 803 includes a lowpass filter 811 for filtering the analog transmit signal to provide a filtered analog signal to a variable gain amplifier (VGA) 821. An up-converter 822 (such as one or more mixers) up converts an amplified analog signal from the VGA 821 in frequency to produce an RF signal. For example, the up-converter 822 may mix the amplified analog signal with a local oscillator (LO) signal from a transmit (TX) LO generator 826. An oscillator such as a TX phase-locked loop (PLL) 824 clocks the TX LO generator 826 for the generation of the TX LO signal. An RF filter 823 filters the RF signal from the up-converter to produce an RF input signal.

A front-end module 810 includes a dual-amplifier system as disclosed herein as represented by a power amplifier 855 for amplifying the RF input signal. It will be appreciated that additional stages of amplification of the RF input signal prior to the power amplifier 855 such as a pre-driver amplifier (not illustrated) and a driver amplifier (not illustrated) may also be used in alternative implementations. An amplified RF output signal from the power amplifier 855 passes through an antenna switch module (duplexer/switch) 870 to an antenna(s) 175 for wireless transmission.

During a receive mode, a received RF signal from the antenna(s) 175 passes through the antenna switch module 870 to a low-noise amplifier. The WTR 803 also includes an RF filter 817 for filtering an amplified RF received signal from the LNA 880. A down-converter 816 (such as one or more mixers) down converts the filtered RF signal from the RF filter 817 in frequency to produce a down-converted analog signal. For example, the down-converter 816 may mix the filtered RF signal with an LO signal from a receive (RX) LO generator 828. An oscillator such as an RX phase-locked loop (PLL) 827 clocks the RX LO generator 828 for the generation of the RX LO signal. Another VGA 814 amplifies the down-converted analog signal from the down-converter 816 to drive a lowpass filter 812 that provides a filtered analog signal to an analog-to-digital (ADC) 806 in modem 102. The ADC 806 recovers the digital baseband signal for further processing by modem 802. It will be appreciated that WTR 803 is merely exemplary and that other transceiver architectures may be used in conjunction with the dual-amplifier systems disclosed herein.

The disclosure will now be summarized in the following example clauses:
Clause 1. A dual-amplifier system, comprising:
   a first amplifier having an output impedance at a first output terminal;
   a second amplifier having the output impedance at a second output terminal; a quadrature hybrid combiner having a through port impedance and a coupled port impedance each equaling an intermediate impedance that is greater than the output impedance and having an output port impedance equaling a load impedance that is greater than the intermediate impedance;
   a first impedance matching network coupled between the first output terminal and a coupled port of the quadrature hybrid combiner, wherein the first impedance matching network is configured to match the output impedance to the intermediate impedance; and
   a second impedance matching network coupled between the second output terminal and a through port of the quadrature hybrid combiner, wherein the second impedance matching network is configured to match the output impedance to the intermediate impedance.
Clause 2. The dual-amplifier system of clause 1, wherein the dual-amplifier system comprises a balanced amplifier.
Clause 3. The dual-amplifier system of clause 1, further comprising:
   an auxiliary amplifier coupled to an isolated port of the quadrature hybrid combiner, the dual-amplifier system comprising a load-modulated balanced amplifier.
Clause 4. The dual-amplifier system of any of clauses 1-3, wherein the quadrature hybrid combiner is configured for a 1:N impedance transformation such that the load impedance is N times greater than the intermediate impedance, wherein N is a real positive number greater than one.
Clause 5. The dual-amplifier system of clause 4, wherein N equals two.
Clause 6. The dual-amplifier system of any of clauses 4-5, wherein the load impedance is 50 ohms.
Clause 7. The dual-amplifier system of any of clauses 4-6, wherein the quadrature hybrid combiner includes a first inductor coupled between an output port and a coupled port and includes a second inductor coupled between a through port and an isolated port.
Clause 8. The dual-amplifier system of clause 7, wherein an inductance of the first inductor equals twice an inductance of the second inductor.
Clause 9. The dual-amplifier system of any of clauses 1-8, further comprising:
a quadrature hybrid splitter configured to split a radio frequency (RF) input signal into a first RF signal and a second RF signal, wherein the first amplifier is configured to amplify the first RF signal and the second amplifier is configured to amplify the second RF signal.
Clause 10. The dual-amplifier system of clause 9, wherein the dual-amplifier system is included within a transceiver of a wireless communication device.
Clause 11. The dual-amplifier system of any of clauses 7-8, wherein the quadrature hybrid combiner further includes a first coupling capacitor coupling between ground and the through port and includes a second coupling capacitor coupling between ground and the isolated port.
Clause 12. A method of operation for a dual-amplifier system, comprising:
   coupling an amplified first RF signal from a first amplifier to a coupled port of a quadrature hybrid combiner having a coupled port input impedance equaling an output impedance of the first amplifier;
   coupling an amplified second RF signal from a second amplifier to a through port of the quadrature hybrid combiner having a through port input impedance equaling an output impedance of the second amplifier;
   combining the amplified first RF signal and the amplified second RF signal to produce an RF output signal at an output port of the quadrature hybrid combiner having an output port impedance that is less than an input impedance of a load; and
   coupling the RF output signal through an impedance matching network to the load, wherein the impedance matching network matches the output port impedance to the input impedance of the load.
Clause 13. The method of clause 12, further comprising:
   driving an isolated port of the quadrature hybrid combiner with an auxiliary signal from an auxiliary amplifier.
Clause 14. The method of clause 12, further comprising:
   coupling an isolated port of the quadrature hybrid combiner to ground through a load having an impedance that is less than the output impedance.
Clause 15. The method of any of clauses 12-14, wherein coupling the RF output signal through the impedance matching network to the load comprises coupling the RF output signal through impedance matching network to at least one antenna.
Clause 16. A dual-amplifier system, comprising:
   a first amplifier configured to amplify a first RF signal into an amplified first RF signal at a first output terminal having an output impedance;
   a second amplifier configured to amplify a second RF signal into an amplified second RF signal at a second output terminal having the output impedance; and
   a quadrature hybrid combiner including a coupled port coupled to the first output terminal and including a through port coupled to the second output terminal, wherein an input impedance of each of the coupled port and the through port equals the output impedance.
Clause 17. The dual-amplifier system of clause 16, wherein the first output terminal and the second output terminal each comprises a collector terminal.
Clause 18. The dual-amplifier system of any of clauses 16-17, wherein the quadrature hybrid combiner includes an output port having an output port impedance that is greater than the output impedance and less than a load impedance, the dual-amplifier system further comprising:
   an impedance transforming network coupled to the output port and configured to match the output port impedance to the load impedance.
Clause 19. The dual-amplifier system of any of clauses 16-18, further comprising:
   at least one antenna coupled to the output port through the impedance transforming network.
Clause 20. The dual-amplifier system of clause 18, further comprising:
   an auxiliary amplifier coupled to an isolated port of the quadrature hybrid combiner.

It will be appreciated that many modifications, substitutions and variations can be made in and to the materials, apparatus, configurations and methods of use of the devices of the present disclosure without departing from the scope thereof. In light of this, the scope of the present disclosure should not be limited to that of the particular implementations illustrated and described herein, as they are merely by way of some examples thereof, but rather, should be fully commensurate with that of the claims appended hereafter and their functional equivalents.

We claim:

1. A dual-amplifier system, comprising:
a first amplifier having an output impedance at a first output terminal;
a second amplifier having the output impedance at a second output terminal;
a quadrature hybrid combiner having a through port impedance and a coupled port impedance each equaling an intermediate impedance that is greater than the output impedance and having an output port impedance equaling a load impedance that is greater than the intermediate impedance;
a first impedance matching network coupled between the first output terminal and a coupled port of the quadrature hybrid combiner, wherein the first impedance matching network is configured to match the output impedance to the intermediate impedance; and
a second impedance matching network coupled between the second output terminal and a through port of the quadrature hybrid combiner, wherein the second impedance matching network is configured to match the output impedance to the intermediate impedance.

2. The dual-amplifier system of claim 1, wherein the dual-amplifier system comprises a balanced amplifier.

3. The dual-amplifier system of claim 1, further comprising:
an auxiliary amplifier coupled to an isolated port of the quadrature hybrid combiner, the dual-amplifier system comprising a load-modulated balanced amplifier.

4. The dual-amplifier system of claim 1, wherein the quadrature hybrid combiner is configured for a 1:N impedance transformation such that the load impedance is N times greater than the intermediate impedance, wherein N is a real positive number greater than one.

5. The dual-amplifier system of claim 4, wherein N equals two.

6. The dual-amplifier system of claim 5, wherein the load impedance is 50 ohms.

7. The dual-amplifier system of claim 5, wherein the quadrature hybrid combiner includes a first inductor coupled between an output port and a coupled port and includes a second inductor coupled between a through port and an isolated port.

8. The dual-amplifier system of claim 7, wherein an inductance of the first inductor equals twice an inductance of the second inductor.

9. The dual-amplifier system of claim 1, further comprising:
a quadrature hybrid splitter configured to split a radio frequency (RF) input signal into a first RF signal and a second RF signal, wherein the first amplifier is configured to amplify the first RF signal and the second amplifier is configured to amplify the second RF signal.

10. The dual-amplifier system of claim 9, wherein the dual-amplifier system is included within a transceiver of a wireless communication device.

11. The dual-amplifier system of claim 7, wherein the quadrature hybrid combiner further includes a first coupling capacitor coupling between ground and the through port and includes a second coupling capacitor coupling between ground and the isolated port.

12. A method of operation for a dual-amplifier system, comprising:
coupling an amplified first RF signal from a first amplifier to a coupled port of a quadrature hybrid combiner having a coupled port input impedance equaling an output impedance of the first amplifier;
coupling an amplified second RF signal from a second amplifier to a through port of the quadrature hybrid combiner having a through port input impedance equaling an output impedance of the second amplifier;
combining the amplified first RF signal and the amplified second RF signal to produce an RF output signal at an output port of the quadrature hybrid combiner having an output port impedance that is less than an input impedance of a load; and
coupling the RF output signal through an impedance matching network to the load, wherein the impedance matching network matches the output port impedance to the input impedance of the load.

13. The method of claim 12, further comprising:
driving an isolated port of the quadrature hybrid combiner with an auxiliary signal from an auxiliary amplifier.

14. The method of claim 12, further comprising:
coupling an isolated port of the quadrature hybrid combiner to ground through a load having an impedance that is less than the output impedance.

15. The method of claim 12, wherein coupling the RF output signal through the impedance matching network to the load comprises coupling the RF output signal through impedance matching network to at least one antenna.

16. A dual-amplifier system, comprising:
a first amplifier configured to amplify a first RF signal into an amplified first RF signal at a first output terminal having an output impedance;
a second amplifier configured to amplify a second RF signal into an amplified second RF signal at a second output terminal having the output impedance; and
a quadrature hybrid combiner including a coupled port coupled to the first output terminal and including a through port coupled to the second output terminal, wherein an input impedance of each of the coupled port and the through port equals the output impedance.

17. The dual-amplifier system of claim 16, wherein the first output terminal and the second output terminal each comprises a collector terminal.

18. The dual-amplifier system of claim 16, wherein the quadrature hybrid combiner includes an output port having an output port impedance that is greater than the output impedance and less than a load impedance, the dual-amplifier system further comprising:
an impedance transforming network coupled to the output port and configured to match the output port impedance to the load impedance.

19. The dual-amplifier system of claim 18, further comprising:
at least one antenna coupled to the output port through the impedance transforming network.

20. The dual-amplifier system of claim 18, further comprising:
an auxiliary amplifier coupled to an isolated port of the quadrature hybrid combiner.
